(19) United States
(12) Patent Application Publication
(10) Pub. No.: US 2014/0234995 A1
(43) Pub. Date: Aug. 21, 2014

(54) METHOD OF FORMING FLEXIBLE AND TUNABLE SEMICONDUCTOR PHOTONIC CIRCUITS

(71) Applicant: Regents of the University of Minnesota, Minneapolis, MN (US)

(72) Inventors: Mo Li, Plymouth, MN (US); Yu Chen, Minneapolis, MN (US)

(21) Appl. No.: 14/182,563

(22) Filed: Feb. 18, 2014

Related U.S. Application Data
(60) Provisional application No. 61/765,921, filed on Feb. 18, 2013.

(51) Int. Cl. H01L 21/306

(52) U.S. Cl. CPC H01L 21/306
USPC 438/22

(57) ABSTRACT

Methods to physically transfer highly integrated silicon photonic devices from high-quality, crystalline semiconductors on to flexible plastic substrates by a transfer-and-bond fabrication method. With this method, photonic circuits including interferometers and resonators can be transferred onto flexible plastic substrates with preserved optical functionalities and performance.

### CROSS-REFERENCE TO RELATED APPLICATION

This application claims the benefit of U.S. Provisional Application No. 61/765,921 filed Feb. 18, 2013, titled METHOD OF FORMING FLEXIBLE AND TUNABLE SEMICONDUCTOR PHOTONIC CIRCUITS, the entire contents of which are incorporated herein by reference for all purposes.

### GOVERNMENT RIGHTS

This invention was made with government support under ECCS1232064 awarded by the National Science Foundation. The government has certain rights in the invention.

### BACKGROUND OF THE INVENTION

Silicon photonics is a technology that can be used to provide high-performance, chip-scale and chip-to-chip communication networks with low cost. Unlike on-chip electrical interconnects in which multiple metal layers are used to transport electrical signals, silicon-photonic interconnects typically use integrated silicon waveguides to route optical signals. Such silicon waveguides typically comprise a path or pattern of crystalline silicon that is formed onto a rigid silicon substrate, wherein optical signals comprising light energy at a given wavelength can be guided within and along the silicon material as an optical waveguide. Such a path or pattern of rigid silicon waveguides can be formed by starting with a top silicon layer as provided onto a silicon substrate, followed by a electron beam lithography and plasma dry etching. Dense wavelength division multiplexing (DWDM) is a technology for implementing on-chip optical communication networks because it offers the ability to effectively reduce the number of waveguides (and consequently to improve the integration density).

A variety of techniques have been investigated for optical multiplexing/demultiplexing on silicon, including: an array-waveguide-grating (AWG) device, an Echelle-grating device, a Mach-Zehnder-based interleaver, cascaded ring-resonator add/drop filters, and coupled-waveguide grating devices. These silicon photonic devices are fixed on-chip and cannot be adapted or re-programmed because of this.

With respect to electrical on-chip interconnects, transfer-and-bond methods have been successfully used to fabricate flexible microelectronics. Typically, electrically conductive material, such as a metal, is deposited onto a flexible insulator layer in a predetermined pattern of electrical interconnects or traces, which flexible insulator can then be bonded to another layer or a device by a bonding technique, such as lamination, welding, or by adhesive.

With respect to photonic on-chip interconnects, flexible microelectronics have been made utilizing a direct deposition of amorphous and low-quality or organic semiconducting materials onto flexible substrates. These flexible microelectronic devices exhibit mechanical flexibility and the bio-compatibility, however, they lack the high electrical performance of crystalline inorganic semiconductor materials.

### SUMMARY

The present invention is directed to the formation of flexible photonic circuits or optical devices. Flexible photonic circuits have tremendous promise in a broad spectrum of optical applications, especially those that cannot be addressed by conventional optical devices in rigid materials and constructions or by flexible microelectronics.

The present invention is particularly directed to methods to physically transfer highly integrated devices made in high-quality, crystalline semiconductors, such as silicon, on to flexible substrates, such a comprising plastic or polymeric materials. The present invention includes methods of making a flexible form of semiconductor photonic devices using a transfer-and-bond fabrication method. With such methods, photonic circuits including, as examples, interferometers and resonators can be formed and then transferred onto flexible substrates with preserved optical functionalities and performance. Moreover, by controllably mechanically deforming an optical circuit or device of the present invention, one or more optical characteristics of the circuit or device can be tuned over a large range. Advantageously, such tuning can be controlled to be reversible. Flexible photonic systems of the present invention that are based on a semiconductor-on-plastic (SOP) platform, opens the door to many future applications, including tunable photonics, opto-mechanical sensors, and biomechanical and biophotonic probes.

Generally, methods of the present invention include, after forming a semiconductor photonic circuit (such as of crystalline silicon) on a rigid silicon substrate, removing substrate material (e.g., from a buried oxide layer such as SiO₂ provided as a top layer to the silicon substrate) from below the semiconductor photonic circuit to reduce the contact area and overall bonding force between the semiconductor circuit and the substrate (the buried oxide layer). With the bonding force decreased, the semiconductor circuit can be removed from the substrate by the application of a sufficient force. Preferably, a flexible material layer is sufficiently bonded to top surface(s) of the semiconductor circuit prior to removal so that the semiconductor circuit is transferred to the flexible layer during the removal step. As such, transfer of the semiconductor circuit from its original substrate to a flexible substrate, such as a plastic substrate, can be done with a precision preferably so that no greater than 10 nanometers of displacement or distortion occurs to any portion of the circuit.

A first particular aspect of the present invention is a method of making a flexible semiconductor photonic circuit by: forming a semiconductor photonic circuit on an insulator layer; creating an undercut semiconductor photonic circuit by removing a portion of the insulator from below the semiconductor photonic circuit while maintaining some insulator below the silicon photonic circuit; applying a flexible layer onto the undercut semiconductor photonic circuit and bonding the flexible layer to the circuit; and separating the flexible layer with the semiconductor photonic circuit bonded thereto from the insulator layer. The flexible layer may have an adhesive surface or may be non-adhesive, as bonding techniques including lamination (the application of heat and pressure), welding, adhesion or the like are contemplated.

Another particular aspect of the present invention is a method of making a flexible semiconductor photonic circuit by: forming a semiconductor photonic circuit on an insulator layer, the circuit having an exposed upper surface area and an interface area with the insulator layer; reducing the interface area to be less than the upper surface area; bonding a flexible layer onto the upper surface area; and separating the flexible layer with the semiconductor photonic circuit bonded thereon from the insulator layer. The step of reducing the interface area can be done by removing a portion of the insulator layer.

In these and other methods of the present invention, a step of removing insulator material can be done by etching. Furthermore, the flexible layer can be a plastic layer, such as polydimethylsiloxane (PDMS), polyester or epoxy, and may preferably comprise a film.

Methods of the present invention for transferring flexible semiconductor photonic devices onto flexible substrates while preserving their optical functionalities, mechanical resilience and tunability, are a significant advance in the creation of a fully integrated flexible photonic system. Semiconductor photonic circuits and devices, as provided onto a flexible substrate, can subsequently be transferred onto a variety of other flexible materials. By using the methods of the present invention and precise alignment techniques, multiple layers of flexible semiconductor photonic devices along with active optical devices, such as made of non-silicon material (such as germanium and III-V semiconductors), can be assembled in three dimensional devices. A complete photonic system thus can be realized with a wide range of potential applications that require mechanical flexibility and biocompatibility, including, for example, implantable biophotonic sensors and optogenetic probes.

These and various other features and advantages will be apparent from a reading of the following detailed description.

### BRIEF DESCRIPTION OF THE DRAWINGS

The invention may be more completely understood in consideration of the following detailed description of various embodiments of the invention in connection with the accompanying drawings, in which:

FIG. 1 is a schematic perspective view of silicon photonic circuits on a flexible substrate, the illustrated circuits including Mach-Zehnder interferometers (MZI) and micro-ring add-drop filters (ADF) patterned onto the flexible substrate;

FIG. 2A is a perspective view of a rigid silicon substrate having a pattern of a semiconductor photonic circuit formed thereon with a buried oxide insulator layer between the silicon substrate and the semiconductor photonic circuit;

FIG. 2B is a cross sectional view of the construct of FIG. 1 taken along line B-B showing the insulator layer covering the silicon substrate with the semiconductor photonic circuit on the insulator layer;

FIG. 3A is a perspective view similar to FIG. 2A but with the insulator layer removed with the exception of insulator material directly between the semiconductor photonic circuit and the silicon substrate;

FIG. 3B is a cross sectional view taken along line B-B of FIG. 3A showing the insulator material being undercut below the semiconductor photonic circuit and between the semiconductor photonic circuit and the silicon substrate;

FIG. 4A is a perspective view similar to FIGS. 2A and 3A but with a flexible film bonded to and covering the semiconductor photonic circuit as formed on the silicon substrate;

FIG. 4B is a cross sectional view taken along line B-B of FIG. 4A showing the flexible film layer bonded to the semiconductor photonic circuit as such is positioned relative to the silicon substrate with undercut insulator material between the semiconductor photonic circuit and the silicon substrate;

FIG. 5 is a perspective view of the device of FIG. 4A with the flexible layer and semiconductor photonic circuit being separated from the silicon substrate and insulator material;

FIG. 6 is a plan view of Mach-Zehnder interferometers (MZI) as provided onto a flexible substrate in accordance with the present invention;

FIG. 7 is an enlarged portion of the semiconductor photonic circuit of FIG. 6 showing the spacing between elements of the semiconductor photonic circuit;

FIG. 8 is a plan view of micro-ring add-drop filters (ADF) as provided onto a flexible substrate in accordance with the present invention;

FIG. 9 is an enlarged portion of the semiconductor photonic circuit of FIG. 8 showing the spacing between elements of the semiconductor photonic circuit;

FIG. 10 is a graphical representation of transmission spectra of an MZI circuit made in accordance with the present invention and measured at its two output ports, showing high extinction ratio and complementary interference fringes;

FIG. 11 is a graphical representation of transmission spectra of a micro-ring ADF made in accordance with the present invention and measured at the “through” and “drop” ports, also showing complementary resonance peaks;

FIG. 12 is a graphical representation of broadband transmission spectrum of a ring resonator made in accordance with the present invention and that is critically coupled to a waveguide on a flexible film, showing a high extinction ratio up to 25 dB;

FIG. 13 is a graphical representation of measured high-Q resonance (circles) and Lorentzian fitting (dashed line) of a ring resonator transferred to a flexible film in accordance with the present invention and with a loaded quality factor of 9.9×10⁴ and an intrinsic quality factor of 1.5×10⁵, where the corresponding value of propagation loss in the waveguide is 3.8 dB/cm;

FIG. 14 is an illustration of a Mach-Zehnder interferometer provided on a plastically deformable flexible layer for mechanical tuning thereof by a compressive force;

FIG. 15 is a cross sectional view in the direction of compression and showing that when the deformable layer is compressed with strain beyond a critical value, a silicon waveguide buckles along with the deformable layer;

FIG. 16 is a graphical representation showing that under increasing compression, the interference fringes in the output of MZI continuously shift toward shorter wavelengths, and when the compression is relaxed, the fringes recover to their initial spectral positions;

FIG. 17 is a graphical representation showing that at given wavelengths (1550 nm and 1564 nm), the measured transmission (symbols) varies sinusoidally with the increasing compressive strain, in agreement with results of the theoretical model (lines);

FIG. 18 is a graphical representation showing that the peak wavelengths (symbols) of the interference fringes shift linearly with the increasing compressive strain toward shorter wavelengths as expected from the theory (lines);

FIG. 19 is an illustration of a micro-ring resonator device on a plastically deformable flexible layer for mechanically tuning by a compressive force;

FIG. 20 is a cross sectional view in the direction of compression and showing that when the deformable layer is compressed with strain beyond a critical value, plural silicon waveguides can be moved relative to one another as the deformable layer buckles and in particular shows that compression as applied to the deformable layer induces an increase in the coupling gap between the micro-ring and the coupling waveguide;

FIG. 21 is a graphical representation showing that under increasing compression, the wavelengths of the resonances only shift slightly whereas the resonance extinction ratios and quality factors changes dramatically;

FIG. 22 is a graphical representations showing quality factor versus applied compressive strain whereas the quality factor increases five folds over a range of 8% strain,

FIG. 23 is a graphical representation showing extinction ratio versus applied compressive strain whereas the extinction ratio can obtain a maximal value of 22 dB when the critical coupling condition is reached at a strain level of 3.7%, which results follow a theoretical model (lines) assuming the coupling gap increases linearly with the applied compressive strain; and

FIGS. 24 through 29 schematically shows sequential steps of a method for making a flexible semiconductor photonic device in accordance with aspects of the present invention.

### DETAILED DESCRIPTION

The present disclosure provides a reliable method to transfer and bond highly integrated and functional semiconductor photonic circuits from standard wafer substrates to flexible substrates, such as flexible plastic substrates, while retaining the optical performance as on the original rigid substrates.

Rather than direct deposition of amorphous and low-quality or organic semiconducting materials directly onto flexible substrates, as done in the prior art, integration of semiconductor photonic circuits on flexible substrates is achieved by the methods of the present invention by physically transferring integrated semiconductor photonic circuit devices from wafer substrates to the flexible substrates. The resulting flexible microelectronic device combines the best properties of two material worlds: the high electrical performance of crystalline inorganic semiconductor materials with the mechanical flexibility and thus bio-compatibility of organic ones. Methods of the present invention can be used with mechanical systems in order to achieve stretchable and even foldable devices, which can be used in unprecedented applications, most notably, such as bio-inspired and implantable biomedical devices. Sophisticated analog and digital CMOS circuits can be transferred from silicon wafer substrates to a variety of substrates such as polymeric films while retaining their photonic performance and functionality in the flexible form and even under mechanical deformation. Beyond silicon microelectronics, the flexible devices of the present invention can be applied to a wide range of micro-devices in diverse materials, including III-V electronics, microwave electronics, carbon electronics, optoelectronics, and plasmonics and meta-materials.

The present invention is directed to methods of transferring semiconductor photonics (rather than flexible microelectronics) into a flexible form. Photonic devices, because of their optical properties, require a more precise process of transferring the circuit from an initial wafer substrate to a flexible substrate. In order to control optical properties and performance precisely, photonic devices have very exact dimensions and physical properties. Examples of photonic optical devices include optical waveguides, optical sensors, interferometers and resonators, micro-ring add-drop filters, and wavelength division multiplexing (WDM) and demultiplexing (WDDM) devices. Most photonic devices have a width of less than 1 micrometer yet a length of one or more millimeters. Silicon photonics may be used for infrared (IR), UV, or visible wavelengths.

An optical waveguide, generally, is a layered structure that guides optical signals. Typical optical waveguide structures include planar waveguides, channel waveguides and optical fibers. An optical waveguide can be a component in an integrated optical circuit or as a transmission medium, such as for communication systems. Optical sensors can be used for various purposes, such as, for example, for pollution sensing in groundwater or for biosensing applications. Wavelength division multiplexing (WDM) and demultiplexing (WDDM) devices enhance the transmission bandwidth of optical communications and sensor systems. WDM technology allows multiple optical channels to be simultaneously transmitted at different wavelengths through a single optical fiber.

Flexible integrated semiconductor or silicon photonics are particularly desirable for various reasons. Crystalline silicon is preferable over plastic or organic materials because of its superior optical properties, including a high refractive index and low optical loss. First, with silicon photonics, the path of light can be bent when it is guided in optical fibers or waveguides. Glass fibers typically can only be bent to a radius of 1 cm before incurring significant loss, however silicon waveguides can make a turn with a radius as small as a few microns without significant loss due to silicon's high refractive index (n=3.5). Second, unlike electronic devices, optical devices can be coupled with each other without being in physical contact; light can propagate through transparent material to couple multiple layers of optical devices. This attribute of contact-free connection enables three-dimensional integration of photonic systems. Third, there are abundant compliant and patternable plastic materials with low refractive index and low optical absorption that are suitable for optical applications, including elastomers such as polydimethylsiloxane (PDMS), polyester such as PET (polyethylene terephthalate) and PEN (polyethylene naphthalate), and epoxies such as SU-8. It is contemplated that any number of other polymeric materials can be utilized for a flexible plastic layer of the present invention so long as the material is capable of bonding with silicon, preferably crystalline silicon, of a semiconductor photonic circuit, whether directly or by way of one or more additional bonding layers and so long as the material has a sufficient level of flexibility based upon any specific application. Other properties may also be relevant depending on the application. In some cases, flexible and plastically deformable materials, such as elastomers are preferred for tunablity, as described below.

Methods of the present invention provide a simple yet reliable method to transfer and bond highly integrated and functional silicon photonic circuits from standard wafer substrates to flexible plastic substrates while retaining essentially the same optical performance and properties as on the original rigid substrates.

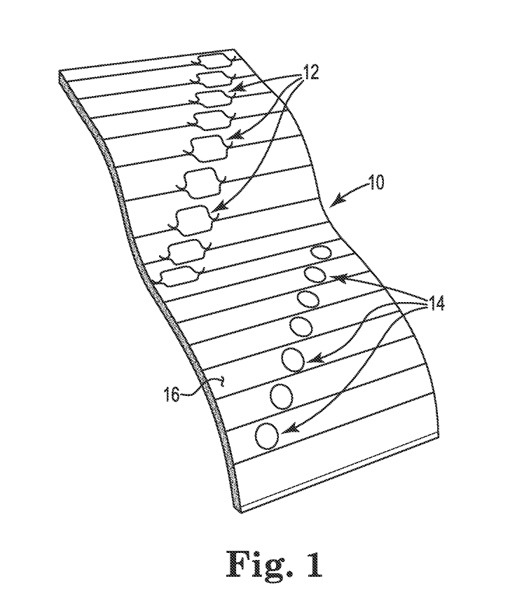

FIG. 1 illustrates a silicon photonic device 10 including multiple semiconductor photonic circuits, including Mach-Zehnder interferometers 12 (MZI) and micro-ring add-drop filters 14 (ADF), as examples, provided onto a flexible layer 16. Preferably, each of the silicon photonic circuits 12, 14 is sufficiently flexible and compliable to move with and remain bonded with the flexible layer 16. One or more semiconductor circuits of any type can be arranged onto a surface of a flexible layer 16 in any number of ways. In the illustrated embodiment of FIG. 1, each circuit 12, 14 is positioned to begin and terminate at opposite edges of the photonic device 10, which edge terminations can be optically connected with other photonic devices, fibers, or other photonic waveguide devices that may be flexible or rigid.

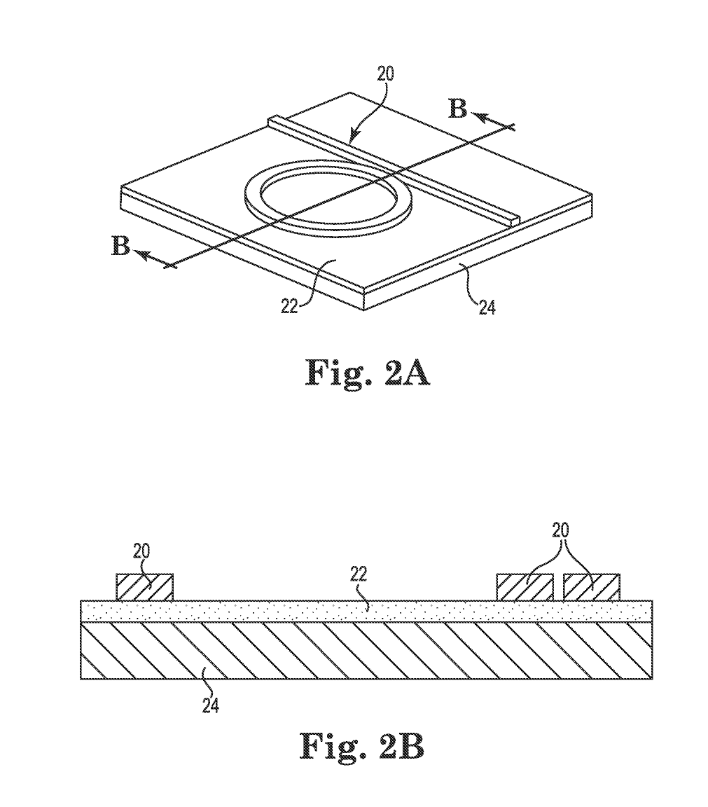

An exemplary fabrication process is illustrated in FIGS. 2A through 5. Referring to FIG. 2A and B, a perspective view and a side view of an initial process stage in accordance with the present invention are shown. A silicon photonic circuit 20, in the shape of an add-drop filter for example, is patterned on an insulating layer 22, such as comprising a buried oxide (BOX) layer of SiO₂ that is preferably layered onto and supported by an substrate 24, such as comprising silicon in a conventional way. As well known, electron beam lithography can be utilized along with plasma dry etching to effectively create precise silicon circuits that themselves comprise crystalline silicon. At this point, the silicon photonic circuit is effectively created onto the insulating layer 22 that is layered onto the silicon substrate 24.

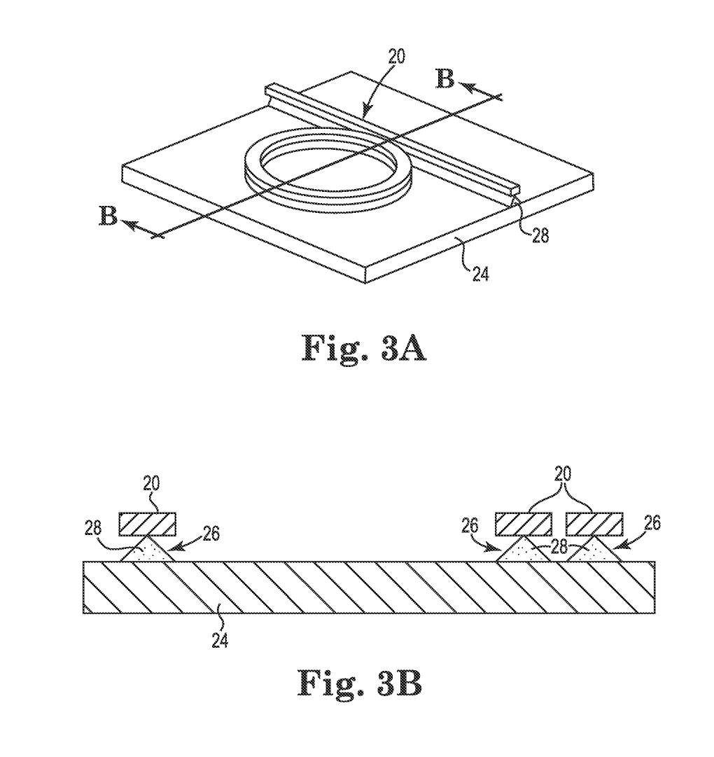

Subsequently, in FIGS. 3A and B, the result of a step of removing a portion of the insulating layer 22 is illustrated. In particular, a BOX layer as the insulating layer 22 can be chemically etched for a precise period of time to not only remove the material that is not covered by the crystalline silicon of the circuit 20 but also to critically undercut the silicon circuit as shown at 26. Undercutting the silicon circuit elements by the controlled etching leaves supporting portions 28 of the insulating layer that still support the circuit elements as they have been patterned. The undercut 26 effectively reduces the interfacial area between elements of the silicon circuit 20 and the insulating BOX layer 22, more specifically the remaining insulating portions 28 so that the total bonding force between the circuit 20 and portions 28 is significantly weakened. Sufficient weakening is determined based upon the ability to achieve the circuit separation step as described below. It is preferable that the undercut 26 causes a reduction in the surface area of the bottom of the silicon circuit 20 that is bonded to the insulating layer 22 material as compared to the total top surface area of the silicon circuit 20.

In accordance with the present invention, as long as a controlled circuit separation can be done as described below, the undercut 26 can be at least the level of sufficiency to do so, but can be greater for easier separation. However, sufficient insulating BOX layer 22 preferably remains under the silicon circuit 20 in order to support the circuit 20 accurately in position and inhibit any displacement. The level of undercut can be controlled by monitoring and controlling the chemical etching process of the BOX material during the removal step. In some embodiments, the width dimension of the circuit 20 is constant, so that the same degree of undercut is present throughout the circuit 20 after the removal step. However, varying degrees of undercut, which may or may not be desired, depending on the application, may be experienced in embodiments where the circuit element widths or other dimensions vary. As compared with a typical circuit 20 width of ______ nm, a preferable degree of the width of the BOX layer 22 left under the circuit 20 after the removal and undercut process is completed is no more than 50 nanometers, and in some embodiments no more than 20 nm. The total bonding area may be decreased by 50%, in some embodiments at least 75%, and in other embodiments at least 90% by the undercutting. In FIG. 3B, the portions 28 formed by the under 26 are illustrated as pyramids in cross section for the sake of illustration and to emphasize the reduction of the bonding area between the circuit 20 and the insulating material of the remaining insulating material portions 28.

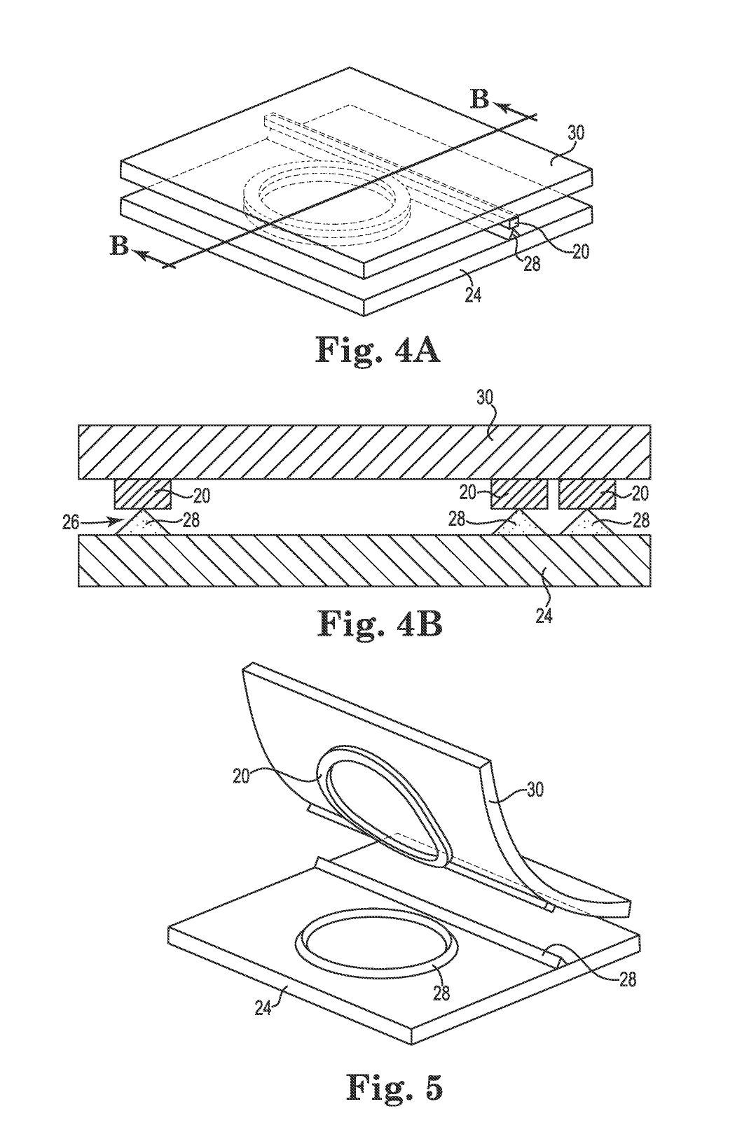

Next, as shown in FIGS. 4A and B, a flexible film 30, such as comprising a polydimethylsiloxane (PDMS) film, is carefully bonded onto the top accessible surfaces of the circuit 20. All top surfaces should be bonded to the flexible film 30 so that the entire silicon circuit 20 is effectively removed in an accurate manner as described below. At this point, an intermediate construct of the present invention comprises the silicon substrate 24 supporting the silicon circuit 20 by way of insulating layer portions 28 and with the silicon circuit also bonded to a flexible layer 30 that overlies the entire silicon circuit.

The flexible film can comprise any material suitable for the purposes of the present invention. For example, many polymeric materials provide sufficient flexibility for applications contemplated for the present invention. A PDMS film is preferred in one aspect of the present invention because of its ability to bond sufficiently with crystalline silicon by a lamination process comprising heat and pressure for a determined period of time. Again, the sufficiency of the bonding is determined based upon the ability for the silicon circuit 20 to separate along with the flexible film from the remaining portions 28 of the insulating material. A typical lamination process includes, after cleaning and drying of the bonding surfaces, the application of a preferably uniform mechanical pressure along with adequate desiccation to ensure conformal contact between the two bonding surfaces and to release water moisture that may be trapped at the interface. The clean and dry surfaces produce a strong, covalent bonding between PDMS and silicon.

It is preferable that adhesives not be used for such a bonding process, but it is contemplated that an adhesive may be utilized depending on the flexible film material that is chosen and in order to create a sufficient bond to facilitate separation as below. As above, the materials that are chosen for a photonic device of the present invention can largely depend on the specific application of use, but with a crystalline silicon circuit preferred for uses of the present invention for its optical qualities, it is thus also preferable that any flexible film chosen have the ability to bond or be bonded adequately with crystalline silicon without causing damage. Other bonding techniques are contemplated based upon the materials chosen for the component features and the specific application for the device. In addition to lamination or heat and pressure bonding, adhesives, welding techniques and other known or developed bonding techniques are contemplated.

For the separation step, the flexible film 30 is preferably peeled along with the silicon circuit 20 from the substrate 24 and remaining portions 28 of insulating material, as shown in FIG. 5, at a constant speed. When the peeling speed is sufficiently high, a PDMS-silicon adhesion force is sufficiently strong to overcome the total bonding force at the silicon-BOX interface (which has been greatly reduced by the previous etching step). An appropriate peeling speed can be empirically determined or otherwise estimated with the goal of achieving an effective separation as above. By the bonding and separation steps, the whole semiconductor photonic circuit(s) 20 can be lifted off from the substrate 24 and thusly transferred on to a flexible film 30, such as a PDMS film. The strong bonding force between silicon and PDMS surfaces ensures high-yield transfer with low occurrence of dislocations and deformations. Because no adhesive material is used in this preferred procedure, contamination to the photonic devices and consequent adverse effects on their optical performance is minimal.

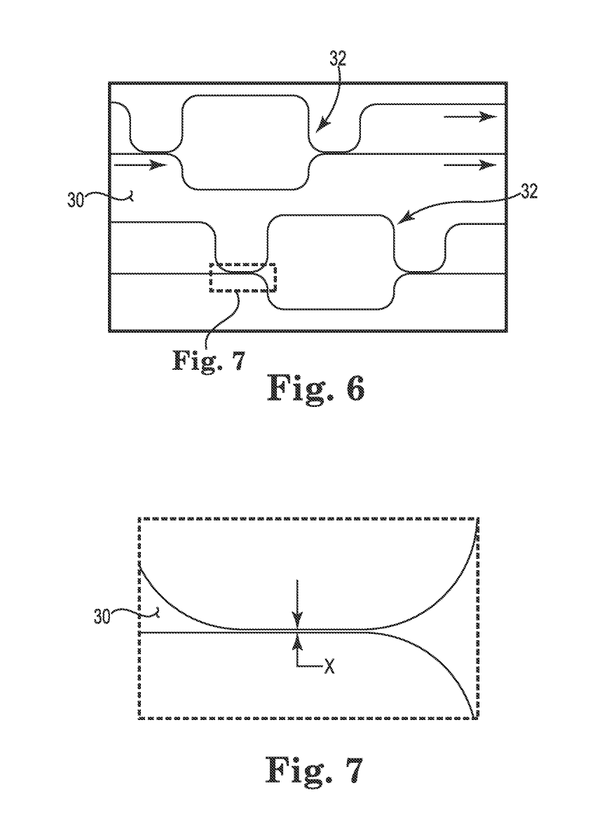

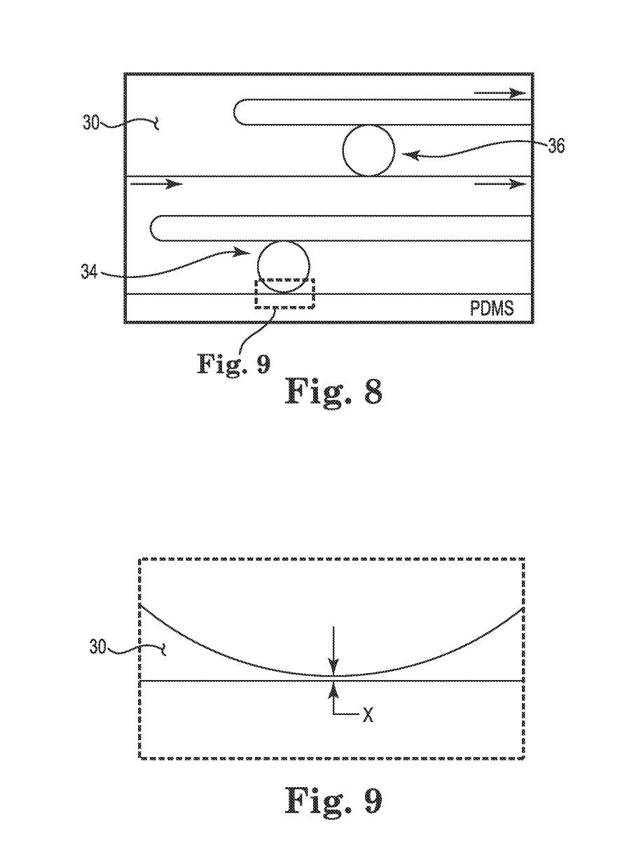

FIGS. 6 and 7 show optical microscope images of typical photonic circuits including Mach-Zehnder interferometers (MZI) 32. FIGS. 8 and 9 show optical microscope images of photonic circuits including micro-ring add-drop filters (ADF) 34. These images of FIGS. 6-9 illustrate the provision of such silicon photonic circuits after being transferred onto a flexible film 30. The illustrated devices can comprise single-mode silicon waveguides such as having a width of 500 nm and a thickness or 220 nm and a total length as long as 1 centimeter with an aspect ratio of 2×10⁴. As shown in the images, an effective transfer is where deformations and dislocations are unnoticeable even at high magnification within the circuits of the transferred devices. Most notably, high magnification images of FIGS. 7 and 9 preferably reveal that coupling gaps X between the waveguide devices, which are as small as 100 nm wide, are preferably to be precisely preserved in the transfer process.

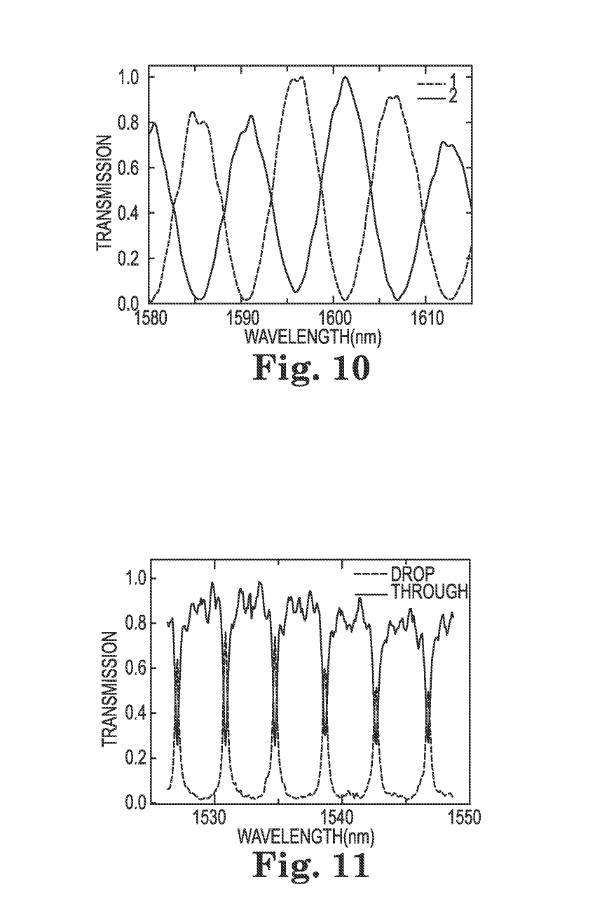

In order to characterize the optical performance of transferred photonic devices of the present invention, a fiber butt-coupling method can be used to couple light from a tunable laser source (not shown), for example, into devices of the present invention and to collect optical output signals to a photodetector (not shown). FIGS. 10 and 11 show typical transmission spectra of a transferred MZI device and a micro-ring ADF device, both in accordance with the present invention. Spectra can be measured at two output ports of a MZI device to determine if they are complementary to each other with a high extinction ratio. Each line in FIG. 10 represents one of the output ports. Similarly, output spectra at the “through” port and the “drop” port of a micro-ring filter preferable can also be determined to see if they are complementary. Such complementary spectra indicates that an optical coupling between waveguides on a flexible film after transfer remain efficient with a very low loss, and in agreement with an observed uniform coupling gap.

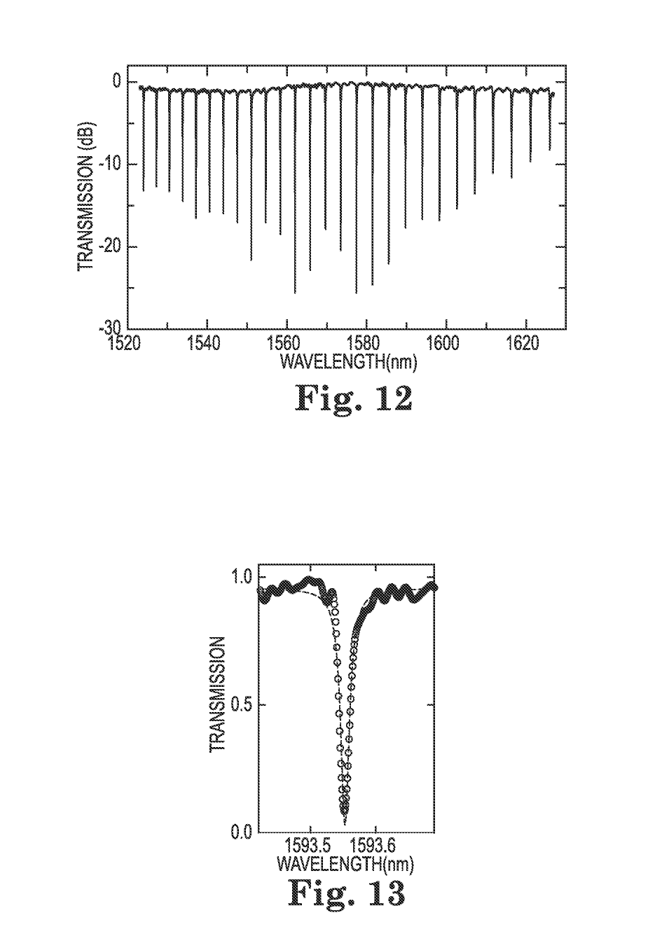

FIG. 12 represents a display of broadband transmission spectrum of a critically coupled ring resonator, showing a group of resonances with the highest extinction ratio of 25 dB. From the measured quality factors Q of the ring resonators, the propagation loss in the transferred waveguide can be determined. FIG. 13 shows an under-coupled resonance at 1593.55 nm with a waveguide loaded Q of 9.9×10⁴, which corresponds to an intrinsic Q of 1.5×10⁵ and a propagation loss of 3.8 dB/cm. This value of propagation loss (i.e., 3.8 dB/cm) is comparable to silicon waveguides on an SOI substrate, which typically have a propagation loss of 3-4 dB/cm (if no special fabrication optimization is used). This demonstrates that transfer methods of the present invention preferably preserve the optical performance and functionalities of the silicon photonic devices on a flexible, plastic substrate.

Furthermore, tunable photonic devices are highly desirable for optical network systems that can be frequently reconfigured. Conventional tuning methods either use electro-optical effects in non-silicon materials such as lithium niobate (LiNbO₃), which is difficult to integrate with silicon devices, or rely on the thermo-optical effect by electrically heating the devices. The heating method, although integrateable, needs to continuously consume electrical power to maintain the tuning

However, in accordance with another aspect of the present invention and based on the determination that optical characteristics of flexible devices can be changed when a substrate is deformed, certain functionalities can be precisely tuned by applying a controlled force, for example, by using a piezoelectric actuator. Because the yield limit of a plastic substrate (e.g., approximately 50% for PDMS) is significantly higher than for crystalline materials (e.g., less than 1% for crystalline silicon), a photonic device on a plastic substrate will respond elastically to the applied force. As such, reversible and reliable tuning can be achieved over a large range.

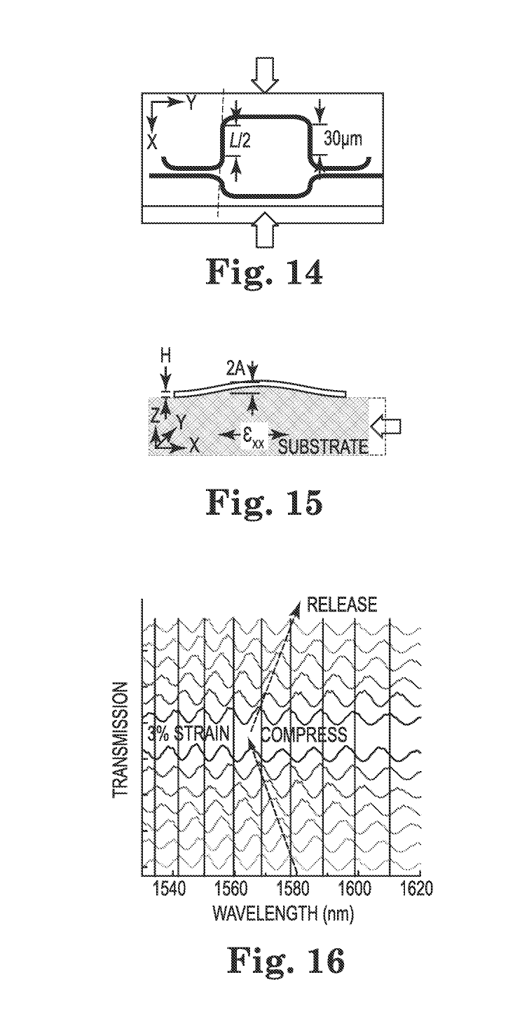

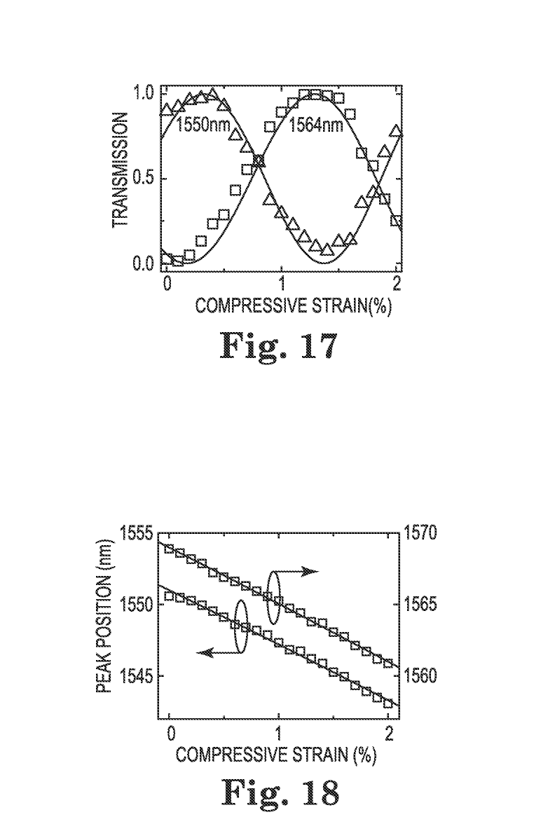

To demonstrate tenability of devices of the present invention, flexible photonic devices made by a method of the present invention were mounted on a precision mechanical stage that could apply compression on the devices. FIGS. 14-18 show the action of and results of tuning a Mach-Zehnder interferometer device by applying a compressive force in the direction normal to the horizontal waveguides in the interferometer arms as shown in FIGS. 14 and 15. As shown in FIG. 16, when such a substrate is compressed in steps to a strain level of 3%, the output interference fringes of the MZI shift continuously toward shorter wavelengths by 12 nm, more than one free-spectral range (FSR=10 nm). When the compression is gradually released, the fringes recover precisely to the initial positions, as marked by the vertical guidelines in FIG. 16. FIG. 17 displays the transmission measured at two fixed wavelengths during tuning, showing sinusoidal changes with the applied strain. The transmission can be tuned between 0 and 1 when the substrate is compressed to a strain level of 1.1%. Similarly, as shown in FIG. 18, the wavelengths of two fringe peaks shift linearly with the applied compressive strain. The transmission of the MZI is given by Tₒ=½+cos(Δφ)/2, where Δφ=2π(n_{eff}L)/λ is the phase difference, n_{eff} is the waveguide mode index and L is the geometric length difference between the two interferometer arms. From the observed blue shift of the interference fringes and the sinusoidal variation of transmission in the figures of FIG. 3, it can be determined that the phase difference Δφ is tuned linearly with an efficiency of 163° per 1% compressive strain (or π per 1.1% compressive strain). Because the elastic modulus of silicon (130 GPa) is five orders of magnitudes larger than that of PDMS (0.3-0.7 MPa), when the applied compressive strain is above a threshold level, the silicon waveguides buckle with the PDMS substrate along the direction of applied strain (x-axis in FIGS. 14 and 15).

Numerous mechanics models have been developed to explain the buckling effect when observed in similar composite structures, such as flexible microelectronics; these models can also be applied to flexible silicon photonics. The buckling amplitude A is given by A=h[−εₐ/ε_{c}−1/(1+0.84εₐ)]^{-1/2}, where h=0.22 μm is the thickness of the silicon layer and εₐ is applied strain (negative for compressive strain). ε_{c}=(3\tilde{E}ₛ/\tilde{E}_{f})^{2/3}/4 is the critical strain above which buckling happens. In the silicon/PDMS composite, the plain-strain modulus are \tilde{E}_{f}=140 GPa for silicon and \tilde{E}ₛ=2.3 MPa for PDMS, thus ε_{c} equals 0.03% which is smaller than the minimal strain (approximately 0.1%) that can be reliably applied in our experiment. Therefore, during the tuning, the waveguides along the direction of applied strain always buckle. The buckling amplitude A at the maximal compressive strain (approximately 3%) applied in the tuning experiment is calculated to be 2.1 gm. Since the geometric length of the waveguide increases when it buckles, the observed decrease in the phase difference Δφ can only be attributed to the reduction of the waveguide mode index n_{eff} from the photo-elastic effect of silicon. Detailed analysis in the supplementary information reveals that n_{eff} of the fundamental TE mode of the waveguide along the direction of strain decreases by Δn_{eff}=η·n³[−ρ₁₂+(ρ₁₁+ρ₁₂)^{υ}]εₓₓ/2, where n, ρ₁₁ and ρ₁₂, υ are silicon's refractive index, elasto-optic coefficients and Poisson ratio, respectively. η=1.15 is the proportional coefficient that relates the change of the waveguide mode index and the change of the material refractive index and can be determined by simulation. εₓₓ is the average normal strain in the buckled waveguide, which is tensile (positive) and can be expressed analytically in an approximate form (supplementary information) or determined numerically by simulation. The results of a theoretical model are plotted in FIGS. 17 and 18, showing good agreement with experimental results.

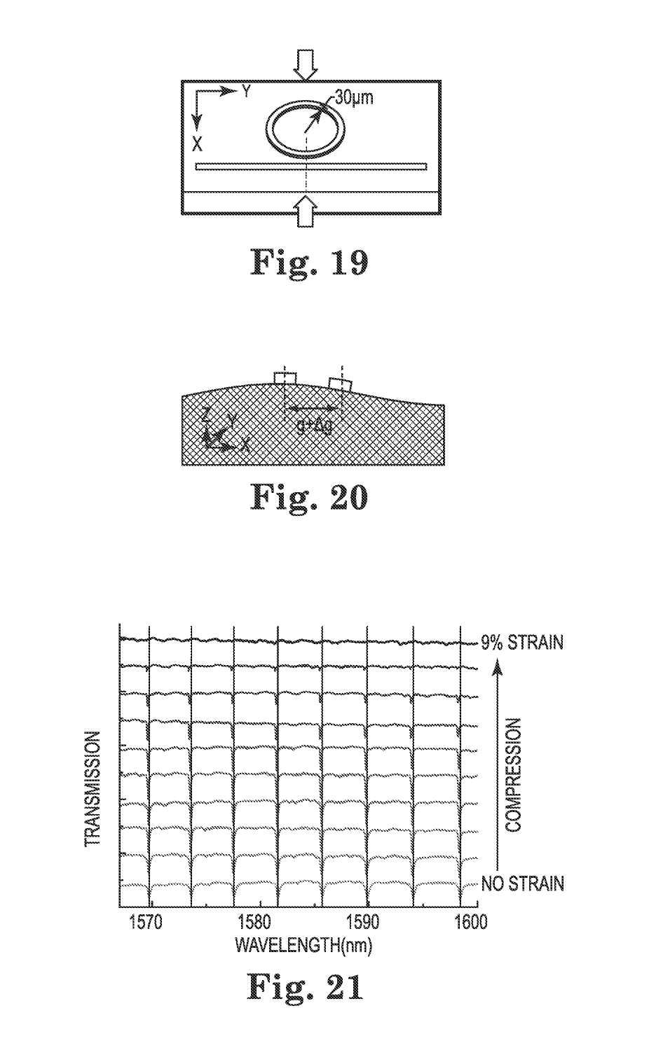

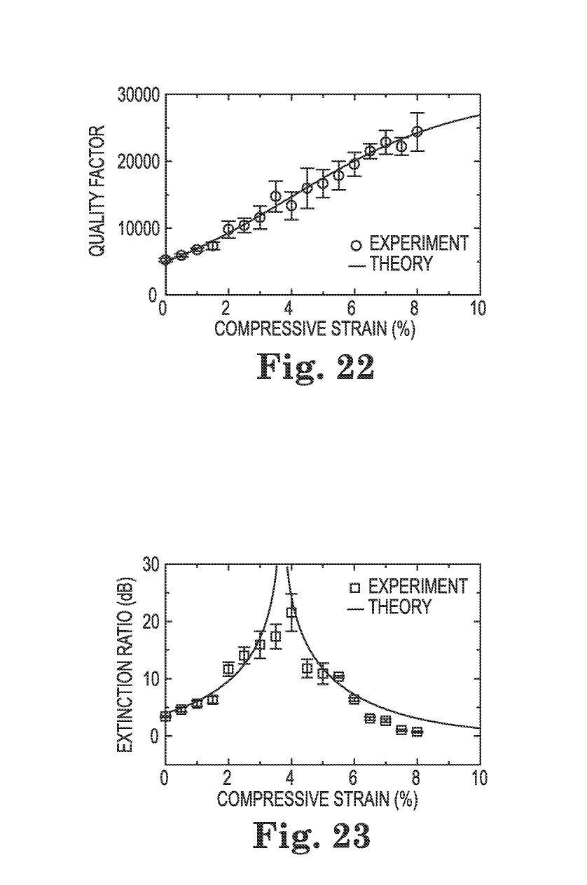

The effect of mechanical tuning on micro-ring resonators is quite different from that of Mach-Zehnder interferometers. As shown in FIG. 21, when a sample is compressed with strain up to 9%, resonance peaks shift slightly by approximately 0.25 nm toward shorter wavelengths, about one sixteenth of the free spectral range (4 nm) of the micro-rings. In contrast, as displayed in FIGS. 22 and 23, both the extinction ratio and the Q factor of the ring change rapidly with applied strain. When the sample is compressed by 4%, the extinction ratio first increases from 3 dB to a maximal value of 22 dB, indicating the resonator reaches the critical coupling condition. At the same time, the loaded Q factor increases from 5×10³ to 1.5×10⁴, suggesting that the intrinsic Q factor of this micro-ring device is approximately 3.0×10⁴. Further compression reduces the extinction ratio until the resonances disappears while the Q factor continues to rise to 2.5×10⁴, approaching the intrinsic value. The tuning behavior can be explained by the increase of the gap between the waveguide and the micro-ring when the substrate is compressed. Compressing the substrate causes buckling of the film and consequently lateral and vertical offset between the waveguides as is illustrated in FIGS. 19 and 20. This increase in the coupling gap reduces the coupling coefficient K and causes the waveguide-ring system to be tuned gradually from the initial over-coupled condition to critically-coupled and further to under-coupled conditions. Analysis using standard theory of optical resonators (see the lines in FIGS. 22 and 23) indicates that the effective coupling gap is tuned from the initial value of 80 nm to about 112 nm to reach critical coupling when 3.7% compressive strain is applied. The resonator's weak spectral sensitivity to mechanical tuning can be understood possibly from the relaxed strain in a ring structure and the symmetry of the photo-elastic effect in a closed loop under uniaxial strain.

The demonstrated an ability to tune the optical properties of flexible semiconductor photonic devices over such a large range can be applied to adaptive and reconfigurable optical systems. In addition, the devices' sensitive response to substrate deformation implies they can be applied as optomechanical sensors to measure mechanical load and displacement with high sensitivity. A flexible format allows sensors to be bonded conformably on curved surfaces such as on animal and human skin.

Flexible devices of the present invention are mechanically robust and can include tunability that is reversible and repeatable. Testing shows that the flexible devices of the present invention can be tuned repeatedly for at least fifty cycles. This testing shows that the optical properties of the devices can be recovered to within 2% range of the original value. Further, the devices do not fail until they are deformed to a very large extent of more than 20% deformation. The failure mechanisms include cracking, slipping and delamination of the silicon layer from the substrate. To further improve the devices' mechanical robustness, mechanical design strategies such as using additional adhesive layers or placing the devices at the strain neutral plane of a multilayer film can be employed.

In accordance with the present invention, the ability to transfer flexible semiconductor photonic circuits onto plastic substrates with preserved optical functionalities, mechanical resilience and tunability, is a significant step toward a fully integrated flexible photonic system. Devices on a flexible (e.g., PDMS) substrate can be subsequently transferred onto another material, such as another plastic material. By advancing the methods of the present invention along with methods used in flexible electronics development, it is further contemplated to assemble multiple layers of flexible silicon photonic devices with active optical devices made of non-silicon material (such as germanium and III-V semiconductors, e.g., GaAs, SiN, GaN) in three dimensions. A complete photonic system thus can be realized, leading toward a wide range of applications that require mechanical flexibility and biocompatibility, such as including implantable biophotonic sensors and optogenetic probes.

### EXAMPLE

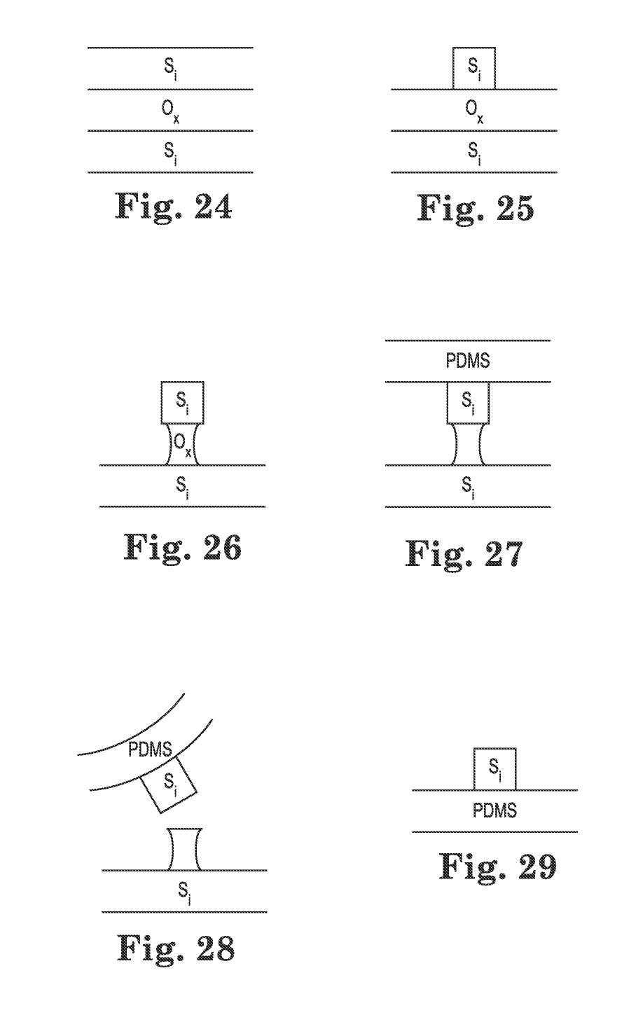

The following exemplary method of the present invention is schematically illustrated in FIGS. 24 through 28. On a standard silicon-on-insulator wafer (SOITEC, Unibound, 220 nm top silicon layer, 3 μm buried oxide layer) (FIG. 24), a silicon photonic circuit was patterned using one-step electron beam lithography (Vistec, EBPG 5000+) and plasma dry etching (Trion II ICP-RIE) with chlorine based chemistry. The resulting circuit is shown in FIG. 25. Subsequently, the substrate was etched in 10:1 buffered oxide etch (BOE) solution, for a precise period of time and at a precisely controlled temperate, to etch the buried oxide (BOX) layer and undercut the silicon device layer, as shown in FIG. 26. The undercut reduced the interfacial area between the silicon and the BOX layer so that the total bonding force between them was reduced without separating them. After etching, the silicon device layer was still affixed to the substrate so that the silicon circuits did not move. In the next step (27), a PDMS film was laminated onto the substrate and the circuit. The PDMS film was made from Sylgard™ 184 (Dow Corning, Inc.) mixture with 10:1 ratio and baked at 90° C. for 1 hour. The film was first thoroughly cleaned with isopropyl alcohol (IPA) and dried in nitrogen gas flow. UV-induced ozone (Jelight UVO-Cleaner) was then used for two minutes to treat the surfaces of the substrate and the PDMS film. Uniform mechanical pressure and adequate desiccation were applied to ensure conformal contact between the two surfaces and to release water moisture trapped at the interface. The clean and dry surfaces produced strong, covalent bonding between the PDMS and silicon. The ends of the waveguides were aligned to the edge of the PDMS film to allow fiber butt-coupling. Finally, the PDMS film was manually peeled off from the substrate at a constant speed (FIG. 28). With sufficiently high peeling speed, the PDMS-silicon adhesion force was adequate to overcome the total bonding force at the silicon-BOX interface; additionally, the bonding area of the PDMS-silicon was greater than the area of the silicon-BOX interface, which had been reduced by the undercut etching step. In this way, the entire silicon photonic layer was lifted off from the substrate and transferred to the flexible PDMS film, as shown in FIG. 29.

The device was mounted on a fiber alignment stage. Two tapered fibers with 2 μm focused spot size were aligned to the ends of the transferred waveguide. Typical fiber to waveguide coupling efficiency is 10%. Mechanical tuning was realized by compressing the device using a manually controlled mechanical stage with a precision of 10 μm.

Thus, methods and embodiments of devices in accordance with the present invention are disclosed. The implementations described above and other implementations are within the scope of the following claims. One skilled in the art will appreciate that the present invention can be practiced with embodiments other than those disclosed. The disclosed embodiments are presented for purposes of illustration and not limitation, and the present invention is limited only by the claims that follow.

What is claimed is:

1. A method of making a flexible semiconductor photonic circuit, the method comprising:
forming a semiconductor photonic circuit on an insulator layer;
removing a portion of the insulator from below the semiconductor photonic circuit while maintaining some insulator below the semiconductor photonic circuit;
applying a flexible layer onto the undercut semiconductor photonic circuit to bond the flexible layer to the circuit; and
separating the non-adhesive flexible layer with the semiconductor photonic circuit bonded thereon from the insulator layer.

2. The method of claim 1 wherein the step of removing a portion of the insulator comprises etching.

3. The method of claim 1 wherein the flexible layer is a plastic layer.

4. The method of claim 1 wherein the flexible layer comprises polydimethylsiloxane (PDMS), polyester or epoxy.

5. The method of claim 1 wherein the flexible layer is a PDMS film.

6. The method of claim 1, wherein the insulator layer comprises a buried oxide layer.

7. The method of claim 1, wherein the semiconductor photonic circuit is a silicon photonic circuit.

8. A method of making a flexible semiconductor photonic circuit, the method comprising:
forming a semiconductor photonic circuit on an insulator layer, the circuit having an exposed upper surface area and an interface area with the insulator layer;
removing a portion of the insulator to reduce the interface area to be less than the upper surface area;
bonding a flexible layer onto the upper surface area; and
separating the flexible layer with the semiconductor photonic circuit bonded thereon from the insulator layer.

9. The method of claim 8, wherein the step of removing comprises removing at least 0.05 micrometer of insulator from each dimension of the interface area.

10. The method of claim 8, wherein the step of removing comprises removing at least 0.1 micrometer of insulator from each dimension of the interface area

11. The method of claim 8, wherein the step of removing comprises removing at least 50% of insulator from the interface area.

12. The method of claim 8, wherein the step of removing comprises removing at least 75% of insulator from the interface area.

13. The method of claim 8, wherein the step of removing comprises removing at least 90% of insulator from the interface area.

14. The method of claim 8, wherein the step of removing comprises etching.

15. The method of claim 8 wherein the flexible layer is a plastic layer.

16. The method of claim 8 wherein the flexible layer comprises polydimethylsiloxane (PDMS), polyester or epoxy.

17. The method of claim 16, wherein the flexible layer is a PDMS film.

18. The method of claim 8, wherein the insulator layer comprises a buried oxide layer.
